(19) United States
(12) Patent Application Publication
(10) Pub. No.: US 2022/0231455 A1
(43) Pub. Date: Jul. 21, 2022

(54) METHOD FOR LOCKING A CONNECTOR ARRANGED ON A CHARGING CABLE TO A MATING CONNECTOR, AND CHARGING STATION FOR CARRYING OUT THE METHOD

(71) Applicant: SMA Solar Technology AG, Niestetal (DE)

(72) Inventors: Raimund Thiel, Bad Zwesten (DE); Jens Klein, Goettingen (DE)

(21) Appl. No.: 17/716,023

(22) Filed: Apr. 8, 2022

Related U.S. Application Data
(63) Continuation of application No. PCT/EP2020/075408, filed on Sep. 10, 2020.

(30) Foreign Application Priority Data
Oct. 9, 2019 (DE) 10 2019 127 197.5

(51) Int. Cl. H01R 13/627; H01R 13/622; H01R 43/26; B60L 53/18; B60L 53/16; B60L 53/60

(52) U.S. Cl. CPC H01R 13/6278; H01R 13/622; H01R 43/26; G01R 31/3835; B60L 53/16; B60L 53/60; B60L 53/18

(57) ABSTRACT

A method for locking a connection between a connector and a mating connector arranged on an electric vehicle is disclosed. The connector is arranged on a charging cable connected to a charging post of a charging station, such as a charging cable fixedly connected to a charging post of a charging station. The connector is associated with a first locking element, and the mating connector is associated with a second locking element, wherein the first locking element and the second locking element cooperate to lock the connection between the connector and the mating connector, and each have an activated state and a deactivated state. The method includes operating the first locking element associated with the connector in an activated state in a first operating mode of the charging station to lock the connection between the connector and the mating connector when the second locking element associated with the mating connector is activated. The method further includes operating the first locking element associated with the connector in a deactivated state in a second operating mode of the charging station to unlock the connection between the connector and the mating connector when the second locking element associated with the mating connector is activated. Additionally described is a charging station which is suitable and set up for carrying out the method.

### REFERENCE TO RELATED APPLICATIONS

This application is a continuation of International Patent Application number PCT/EP2020/075408, filed on Sep. 10, 2020, which claims priority to German Application number 10 2019 127 197.5, filed on Oct. 9, 2019. The contents of the above-referenced patent applications are hereby incorporated by reference in their entirety.

### FIELD

The disclosure relates to a method for locking a connection between a connector of a charging station and a mating connector of an electric vehicle. The disclosure further relates to a charging station comprising a charging post, a charging cable connected to the charging post, and a connector arranged on the charging cable, which charging station is suitable and set up for carrying out the method.

### BACKGROUND

An electric vehicle (EV), in particular an electric car, can be charged at public charging stations in different ways. In a first variant, the charging process takes place via a charging cable owned by a user of the EV. In this case, the charging cable has a connector at each of its ends, which connectors are connected in each case to a complementary mating connector on the EV and on a charging post associated with the charging station. Such a charging station or its charging post thus comprises a complementary mating connector, but generally no charging cable fixedly connected to the charging post. In a second variant, the charging process takes place via a charging cable that is generally fixedly or non-detachably connected to a charging post of the charging station. Such a charging cable has only one connector at its free end, which connector is connected to a complementary mating connector on the EV. Conventional charging stations are designed either for the first variant only, for the second variant only, or for both the first variant and the second variant. They therefore have: (i) either exclusively a complementary mating connector for connecting a separate charging cable, (ii) exclusively a charging cable fixedly connected to the charging station, or (iii) a combination of a complementary mating connector and a charging cable fixedly connected to the charging station.

During the charging process, a connection between the connector of the charging cable and the complementary mating connector on the EV is usually mechanically locked. Here, an operating principle of a conventional locked connection is shown in FIGS. 1 and 2. FIG. 1 shows a connector 1 arranged at the end of a charging cable—not shown in FIG. 1. On its housing 4, the connector 1 has at least one, often several, receiving openings 3 as first locking elements 2, each of which is engaged by an activatable and deactivatable second locking element arranged on the EV. As shown in FIG. 2, the second locking element 6 is, for example, an axially displaceable pin 7, which, in an activated state of the second locking element 6, engages in one of the receiving openings 3 of the connector 1 on the charging cable side. This is intended to prevent a disconnection of the connector 1 and mating connector 5 under load—i.e. when there is significant current flow between the charging station and EV. The mechanical locking typically remains in place until it is unlocked by a user of the EV, for example by an operation of the key associated with the EV. During the unlocking process, the pin 7 of the second locking element 6 moves axially out of the receiving opening 3 of the connector 1, thus allowing the connection between the connector 1 and the mating connector 5 to be disconnected.

The operating principle of a conventional locking of connector 1 and mating connector 5 simultaneously pursues the purpose of protecting a charging cable that is in the possession of an EV user—i.e., is not fixedly connected to the charging post of the charging station—from access by third parties and possible theft. However, a disadvantage here is that the connection between the connector and the mating connector can often also be locked long after the charging process has ended, for example, because the EV user in question is not on site at that time to unlock the connection. The conventional locked connection is brought about exclusively by activating the second locking element of the EV and can be unlocked exclusively by deactivating the second locking element. In this context, the connection is locked and unlocked regardless of whether the charging cable is a charging cable that is fixedly connected to the charging post of the charging station or a separate charging cable. Therefore, a charging station that has a charging cable fixedly connected to a charging post of the charging station is blocked for a subsequent charging process. The blocking continues until the user of the EV of which the mating connector is locked to the connector of the charging cable is available on site to unlock the connection between the connector and mating connector. An already currently weak infrastructure of charging stations is thus not fully utilized, as the charging station is thus prevented from being able to be used for a second EV immediately after completion of the charging process at a first EV.

Document DE 10 2013 015 954 A1 discloses a method for charging an energy supply unit of an electric motor vehicle with electrical energy from an electric charging station having a charging cable. In this process, the charging cable is locked to the electric motor vehicle before a charging process is started. The locking of the charging cable is released by the electric motor vehicle after receipt of a universal release signal if the charging process has been completed at that time.

Document US 2019/0061538 A1 discloses an electric vehicle having a storage device that can be charged with electrical energy via a charging cable. The vehicle comprises: an inlet designed to receive a charging connector disposed at an end of the charging cable, and a cable locking mechanism disposed in the vicinity of the inlet. The cable locking mechanism can switch between a locking state and an unlocking state. The electric vehicle further comprises a control device configured to charge the storage device in a first operating mode with a first current value when the charging connector and the inlet are connected to each other and the cable locking mechanism is in the locked state. The control device is further configured to charge the storage device in a second operating mode with a second current value that is lower than the first current value when the charging connector and the inlet are connected to one another and the cable locking mechanism is in the unlocked state.

Document DE 102018123314 A1 discloses a charging connector on the charging cable side for insertion into a charging socket on the charging station side for charging a traction battery of a motor vehicle via a charging cable. The charging connector has a locking undercut on the outside, which is engaged behind by a locking element of the charging station to lock the charging connector in the charging socket. The charging connector additionally has a manual emergency release with an active element to ensure that the locking element no longer engages behind the locking undercut when the emergency release is manually actuated.

### SUMMARY

The disclosure addresses the problem of specifying a method for locking a connection between a connector and a complementary mating connector, wherein the connector is arranged on a charging cable of a charging post associated with a charging station. On the one hand, the method is intended to reliably prevent disconnection of the connection under load, but on the other hand it is not intended to block the charging station unnecessarily for subsequent charging operations. In particular, such a charging station is not to be unnecessarily blocked for subsequent charging operations if the charging station has a charging post with a charging cable fixedly connected to the charging post. A further problem addressed by the disclosure is that of presenting a charging station suitable for carrying out the method.

The method according to the disclosure is aimed at locking a connection between a connector of a charging station and a mating connector arranged on an electric vehicle (EV). In this case, the connector is arranged at one end of a charging cable, which is connected with its other end to a charging post of the charging station. A first locking element is associated with the connector and a second locking element is associated with the mating connector. The first locking element and the second locking element each have an activated state and a deactivated state, and cooperate to lock the connector and the mating connector together. The method comprises operating the first locking element associated with the connector in an activated state in a first operating mode of the charging station to lock the connection between the connector and the mating connector when the second locking element associated with the mating connector is activated. The method also comprises operating the first locking element associated with the connector in a deactivated state in a second operating mode of the charging station to unlock the connection between the connector and the mating connector when the second locking element associated with the mating connector is activated.

The charging cable can, in one embodiment, be a charging cable that is fixedly connected to the charging post of the charging station. A charging cable that is fixedly connected to the charging post is understood in one embodiment to mean a charging cable that cannot be disconnected from the charging post or from the charging station, or can only be disconnected by a specialist personnel specially authorized by the operator of the charging station. Such a charging cable can, for example, be wired, for example screwed, to the charging post at one end—usually within a housing of the charging post—and can have the connector at its other end. However, a fixedly connected charging cable can also have a connector at both ends, one of which is fixedly connected to a complementary mating connector on the charging post, for example, via a locked padlock.

Advantageously, in one embodiment the EV can be charged in the first operating mode of the charging station. During the first operating mode, the connector and the mating connector are locked together. The first locking element of the connector and the second locking element of the mating connector are each present in their activated state. Disconnection of the connector and mating connector in the first operating mode of the charging station is thus reliably prevented by the interaction of both activated locking elements. Even in the first operating mode of the charging station, however, the charging process can be interrupted by a user of the EV, for example, at the user's specific request. In this case, the second locking element associated with the mating connector can be deliberately set to a deactivated state. However, such deactivation requires that the EV user consciously initiate it, as it is typically performed in conjunction with another function of the EV, for example, a locking mechanism of the vehicle. Alternatively, or cumulatively, it is possible for the second locking element to be placed in the deactivated state in response to a separate release signal. The release signal may be generated, for example, via a vehicle key associated with the EV. In the deactivated state of the second locking element, it is possible to disconnect the connector and mating connector even if the first locking element associated with the connector is activated.

Advantageously, in one embodiment, when the EV charging process is complete, the charging station may be in the second operating mode. Specifically, when the charging process is nearing completion or has been completed, for example, because an energy storage device of the EV has reached its individual target value for stored energy, the charging station may switch to the second operating mode. In the second operating mode of the charging station, the first locking element associated with the connector is in its deactivated state. In the deactivated state of the first locking element, disconnection of the connector and mating connector is also possible when the second locking element associated with the mating connector is in its activated state. In the deactivated state of the first locking element, the connection between the connector and of the mating connector is unlocked and disconnection of the connection is possible regardless of whether the second locking element associated with the mating connector is in its activated state or its deactivated state.

Overall, in one embodiment of the method, the connection between the connector and the mating connector is only locked when both the first locking element of the connector and simultaneously the second locking element of the mating connector are each in their activated state. As soon as at least one of the locking elements of the connector and mating connector is in the deactivated state, the connection between the connector and the mating connector is unlocked and can be disconnected. It is understood that an unlocked connection is also present when both the first locking element of the connector and the second locking element of the mating connector are each in their deactivated state.

The method enables an EV user of a second EV to disconnect the connection between the connector and mating connector when the charging process on a first EV has been completed. The EV user of the second EV can thus start a new charging process on the second EV after completion of the charging process on the first EV, without the need for an unlocking process initiated by the EV user of the first EV—for example triggered by the second locking element of the mating connector. Rather, the connection between the connector and the mating connector can be unlocked automatically by the charging station, which detects when the charging process of the EV has been completed based on measurements of electrical variables that take place anyway during the charging process. Thus, once the charging process has been completed, the charging station is not blocked by the fact that the connection between the connector and mating connector remains locked because the second locking element of the mating connector is in its activated state. At the same time, however, an unintentional disconnection of the connection between the connector and mating connector during the charging process of the EV is reliably prevented due to the interaction of the activated first locking element of the connector and the activated second locking element of the mating connector.

In one embodiment of the method, the first locking element, and optionally also the second locking element, can be activated and/or deactivated electromotively or electromagnetically. Advantageously, a transition from the activated state of the first locking element to the deactivated state of the first locking element can take place depending on a measurement of electrical variables in the connector and/or in the charging post of the charging station. Such electrical variables, for example a battery voltage of the energy storage device associated with the EV and a charging current, are usually detected by the charging station anyway. In this way, the charging station can determine when a charging process of the EV is complete. Usually, only a battery voltage—and thus an energy content of the battery—is kept constant after the charging process is complete, which is done with a very low current, possibly also a current of OA. In this state, disconnection of the connection between the connector and the mating connector is possible without the risk of arcing, and the connection can be unlocked or is unlocked. Completion of the charging process can be achieved in different ways or triggered by different events. For example, termination of the charging process may be triggered by the storage device of the electric vehicle being fully charged to its maximum possible energy content. Alternatively, it is possible to trigger the completion of the charging process by reaching or exceeding a predefined charging time and/or a predefined charging energy. To unlock the connection, a control signal can be transmitted from the charging post to the connector. In response to the control signal, an electromotive or electromagnetic actuator in the connector can act on the first locking element and set the first locking element to the activated state or to the deactivated state. In this context, the control signal can in principle be transmitted by radio or by cable. In an advantageous embodiment of the method, however, the control signal for activating and/or deactivating the first locking element assigned to the connector is transmitted from the charging post by cable, in particular via a line of the charging cable designed for power transmission, a communication line already present in the charging cable, or a separate signal line of the charging cable.

Locking, as well as unlocking of the connection, can also take place without transmission of a control signal from the charging post to the connector. This is possible, for example, if a current measurement, as well as a generation of the control signal to the actuator associated with the first locking element, takes place in the connector itself, for example, via a control unit arranged in the connector. In an alternative embodiment of the method, a transition from the activated state of the first locking element to the deactivated state of the first locking element can be effected via an actuator associated with the first locking element, which actuator is driven by a magnetic field generated by a charging current flowing via the connection between connector and mating connector. In this case, the actuator can be held in a first position by a spring acting mechanically on the actuator, in which position the first locking element is in the deactivated state. During an EV charging process, however, a significant charging current flows through the charging cable and simultaneously through the connection between connector and mating connector. The charging current generates a magnetic field circularly surrounding a current-carrying lead of the charging cable, which magnetic field acts on the actuator and generates a force on the actuator that opposes the force of the mechanical spring. Therefore, if the magnetic field is sufficiently strong, the actuator can be moved by the magnetic field to a position in which the first locking element is in the activated state. When charging is complete, the charging current is sufficiently low to allow the force of the mechanical spring to move the actuator back to the first position.

In a further embodiment, the first locking element associated with the connector may have a receiving opening arranged in a housing of the connector. In this case, the receiving opening can have a closable edge region along its circumference. The second locking element associated with the mating connector can include a displaceable, in particular axially displaceable pin which, in its activated state, engages in the receiving opening of the first locking element and thus mechanically locks the connection between the connector and the mating connector. In this context, it is not absolutely necessary that the periphery of the receiving opening is completely closed when the edge region is closed. Rather, it is possible for the circumference of the receiving opening to be slightly open in a vicinity of the edge region, even when the edge region is closed. In this case, however, the opening distance is smaller than a diameter of the second locking element embodied as a pin, so that the pin cannot be moved out of the receiving opening of the first locking element in the activated state of the second locking element. For an unlocking of the connector and the mating connector, the edge region of the receiving opening can open or be opened to an opening distance that exceeds a diameter of the pin, so that the pin can be moved out of the receiving opening even when the second locking element is activated, but in the deactivated state of the first locking element. In this case, the opening distance can be increased even before relative movement of the connector and mating connector, for example electromotively or electromagnetically. However, it is also within the scope of the disclosure that the opening distance is increased by a relative movement of connector and mating connector. The latter is the case, for example, if the closable edge region of the receiving opening is kept closed in the closed state via an activated locking means, while in the non-closed state the locking means is deactivated and allows the edge region to be opened. Specifically, the closable edge region of the receiving opening can be closed or narrowed via a lockable bridge which is rotatably or slidably mounted in the housing in the deactivated state of the first locking element.

An EV charging station according to the disclosure comprises a charging post, a charging cable connected to the charging post and a connector arranged on the charging cable. The charging cable may, for example, be a charging cable that is fixedly connected to the charging post. The connector is designed to establish a locked connection to a mating connector of the electric vehicle. For this purpose, the connector has a first activatable and deactivatable locking element that is designed to interact with a second activatable and deactivatable locking element of the mating connector for the purpose of locking. In a first operating mode, the charging station is designed and set up to operate the first locking element associated with the connector in an activated state to lock the connection between the connector and mating connector when the second locking element of the mating connector is activated. Additionally, in a second operating mode, the charging station is designed and set up to operate the first locking element associated with the connector in a deactivated state to unlock the connection between the connector and mating connector or keep said connection unlocked even when the second locking element of the mating connector is activated. The charging station additionally has a control unit for actuating the connector. In this embodiment, the control unit, if necessary in conjunction with an actuator assigned to the first locking element, is designed and set up to lock the connector to the mating connector in accordance with the method according to the disclosure. The advantages already explained in conjunction with the method result.

In one embodiment of the charging station, the first locking element associated with the connector may have a receiving opening. The receiving opening may be arranged in a housing of the connector and may have a closable edge region along its circumference. In the first operating mode of the charging station, the receiving opening can be designed here to at least partially enclose a second locking element designed as a pin in its activated state in such a way that a movement of the activated second locking element out of the receiving opening, and thus a relative movement of the connector and the mating connector, is reliably prevented. Here, the first locking element in its deactivated state may be designed and set up to open a previously completely closed edge region of the receiving opening or to increase an opening distance d of a previously not completely closed edge region such that the opening distance d exceeds a diameter of the second locking element designed as a pin. For example, the first locking element of the connector can have a bridge which, in the deactivated state of the first locking element, is rotatably or displaceably mounted in the housing. By contrast, in an activated state of the first locking element, rotation and/or displacement of the bridge is prevented by a suitable locking means acting on the bridge. In this way, relative movement between the connector and mating connector is enabled when the first locking element is in its deactivated state, even when the second locking element is in its activated state. In this case, the connection between connector and mating connector is unlocked and can be disconnected. By contrast, the connection between connector and mating connector is securely locked when the first locking element of the connector and the second locking element of the mating connector are each simultaneously in their activated state.

In an advantageous embodiment, the charging station can have a signaling device that is set up to indicate the currently present operating mode of the charging station. The signaling device can be arranged on the connector and/or on the charging post of the charging station. By means of the signaling device, it can be immediately identified whether the charging station is currently operating in the first operating mode or in the second operating mode. In this way, it is immediately apparent, especially in the case of a plurality of charging stations, at which of the plurality of charging stations a charging process is still in progress or has already been completed. Furthermore, the charging station can have an emergency switch, in particular a lockable emergency switch, wherein the emergency switch is designed to put the charging station into the second operating mode. In this way, the connection between the connector and mating connector can be unlocked, in particular even when the second locking element of the mating connector is activated. Thus, it can be made possible for an authorized person, for example, a service technician responsible for the charging station, to bring about a disconnection of the connector and the mating connector even if the event otherwise terminating the charging process has not yet been reached. The lockable emergency switch ensures that the emergency switch can only be operated by persons who have a release element assigned to the locking mechanism of the emergency switch. The release element can be designed as a mechanical key. Alternatively, however, the locking mechanism can also be designed as a sensor to detect a release element that identifies the authorizing person, for example, a fingerprint.

In an advantageous embodiment of the charging station, the first locking element can have an electromotive or electromagnetic drive. In particular, the first locking element of the connector can have an electromagnetic or electromagnetic release device. A release device is understood, in one embodiment, to mean a locking means associated with the first locking element and acting, for example, on the lockable edge region.

The charging station can comprise a measuring device connected to the control unit for detecting electrical variables during the charging process, for example, an electrical voltage of an energy storage device associated with the EV and/or a charging current. In this context, the control unit of the charging station may be designed and set up to operate the charging station either in the first operating mode or in the second operating mode depending on the detected electrical variables.

Advantageous embodiments of the disclosure are indicated in the following figure description and dependent claims, the features of which can be used individually and in any combination with one another.

### BRIEF DESCRIPTION OF THE FIGURES

The disclosure is illustrated below with the aid of figures, which show:

FIG. 1 illustrates an embodiment of a conventional connector;

FIG. 2 illustrates an operating principle of a conventional locking of a connection between connector and mating connector;

FIG. 3 illustrates a charging station for an electric vehicle according to the disclosure in one embodiment;

FIG. 4a illustrates a view of a locked connection between connector and mating connector in a first embodiment of the method according to the disclosure;

FIG. 4b illustrates a view of an unlocked connection between connector and mating connector from FIG. 4a in the first embodiment of the method according to the disclosure;

FIG. 5a illustrates another view of the locked connection between connector and mating connector from FIG. 4a;

FIG. 5b illustrates another view of the unlocked connection between connector and mating connector from FIG. 4b.

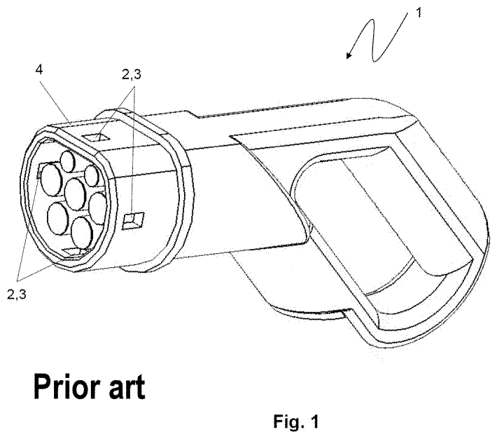

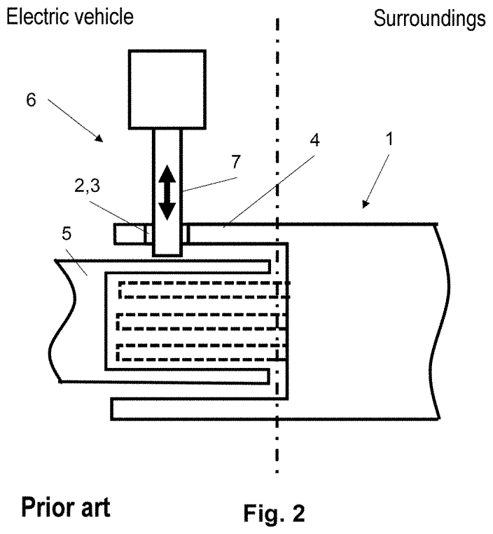

### DETAILED DESCRIPTION

The disclosure relates to a method for locking a connection between a connector of a charging station and a mating connector of an electric vehicle. The connector is arranged at one end of a charging cable connected to a charging post of the charging station. In particular, the method aims to establish a locked connection between the connector and the mating connector in a first operating mode of the charging station and to establish an unlocked connection between the connector and the mating connector in a second operating mode of the charging station. In particular, the charging cable may be a charging cable fixedly connected to the charging station. The disclosure further relates to a charging station comprising a charging post, a charging cable connected to the charging post, and a connector arranged on the charging cable, which charging station is suitable and set up for carrying out the method.

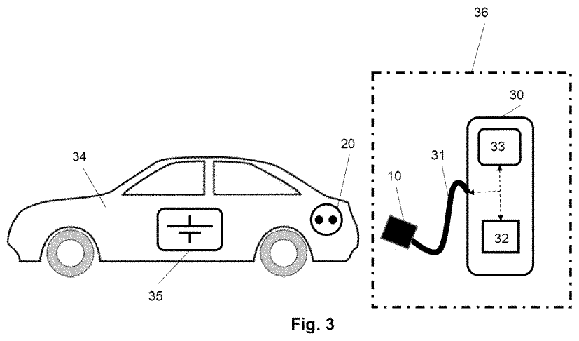

FIG. 3 illustrates an embodiment of a charging station 36 according to the disclosure for an electric vehicle 34. The charging station 36 comprises a charging post 30 and a charging cable 31 fixedly connected to the charging post 30. The charging cable 31 fixedly connected to the charging post 30 is screwed at one end inside a housing of the charging post 30 in the example embodiment illustrated in FIG. 3. It is thus connected fixedly (in the sense of being non-detachable or not readily detachable) to the charging post 30. The charging cable 31 has a connector 10 at its other end, which is designed or otherwise configured to be connected to a complementary mating connector 20 of the EV 34. Via the connection between connector 10 and mating connector 20, a charging current can flow during a charging process of the EV 34 to charge an energy storage device 35 of the EV 34 to a target value. The charging station 36 additionally comprises a measuring device 33 for detecting electrical variables associated with the charging process, for example a voltage of the energy storage device 35 or a charging current, and a control unit 32 connected to the measuring device 33.

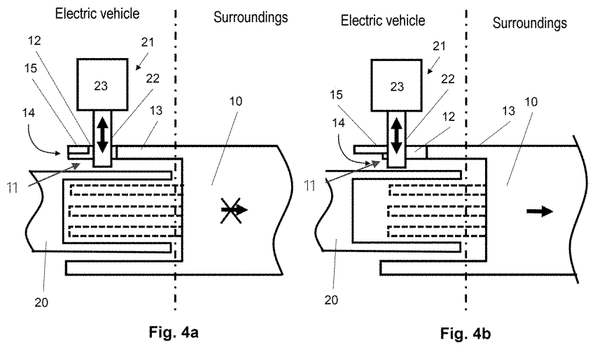

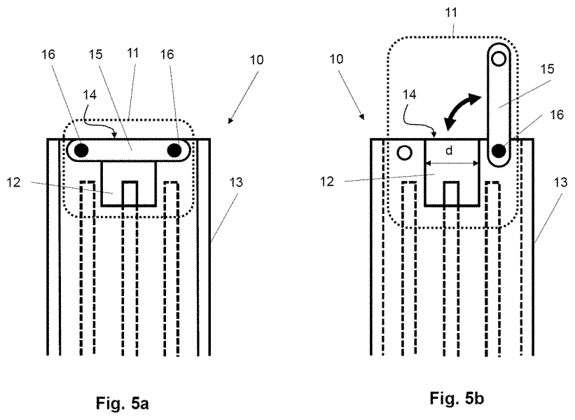

In one embodiment, the charging station 36 can be operated in two operating modes via the control unit 32. In this case, a charging process of the EV 34 takes place in a first operating mode of the charging station 36. In the first operating mode, the connector 10 is connected to the mating connector 20 in a locked manner. For this purpose, a first locking element 11 of the connector 10 and a second locking element 21 of the mating connector 20 are each present in the activated state (see FIGS. 4a and 5a). Disconnection of the connection between connector 10 and mating connector 20 in the first operating mode of the charging station 36 is thus reliably prevented. Arcing due to an unintentional disconnection and a resulting damage to components of the charging station 36 and/or the EV 34 is thus prevented. When the charging process is complete, the charging station 36 is operated in the second operating mode by the control unit 32. Here, the first locking element 11 of the connector 10 is in its deactivated state, whereby the connection between the connector 10 and mating connector 20 is unlocked (see FIGS. 4b and 5b). Disconnection of the connection between the connector 10 and the mating connector 20 is thus made possible even when the second locking element 21 of the mating connector 20 is activated. In one embodiment, the control unit 32 is designed or otherwise configured and set up to operate the charging station 36 in the first operating mode or in the second operating mode depending on the electrical variables detected via the measuring device 33.

FIGS. 4a, 4b, 5a, and 5b show views of a lockable connection between a connector 10 and a mating connector 20 established using an embodiment of the method of the disclosure, moreover established with a connector 10 of the charging station 36 according to the disclosure as per FIG. 3. Here, FIGS. 4a and 5a show the locked state of the connection, while FIGS. 4b and 5b illustrate the unlocked state of the connection. In addition, FIGS. 4a and 4b show the connection from a side view, while FIGS. 5a and 5b show the corresponding connection in a plan view. In the following, the operating principle of an embodiment of the method for producing a locked or unlocked connection is explained with reference to FIGS. 4a, 4b, 5a and 5b.

During a charging process of the EV 34, the charging station 36 is in the first operating mode. Accordingly, the first locking element 11 of the connector 10 as well as the second locking element 21 of the mating connector 20 are each present in their activated state. The first locking element 11 of the connector 10 includes a receiving opening 12, the second locking element 21 includes an axially displaceable pin 22, which is driven via an electromagnetically acting actuator 23. An edge region 14 of the receiving opening 12 running along a circumference of the receiving opening 12 is closed via a locked bridge 15. To close the receiving opening 12, the bridge is fixed in position on a housing 13 of the connector 10 via locking means 16. In the locked state of the connection, the pin 22 engages through the closed receiving opening 12 and thus prevents a relative movement of the connector 10 in relation to the mating connector 20. Disconnection of the connection is thus not possible, which is illustrated schematically by the crossed-out arrow in the connector 10 in FIG. 4a.

An imminent completion of the charging process is determined by the charging station 36, for example, on the basis of electrical variables associated with the charging process, which are detected by the measuring device 33 and evaluated by the control unit 32. In one embodiment, the charging station 36 can determine here whether a previously specified target value for an energy storage 35 of the EV 34 has been reached. If completion of the charging process is identified by the charging station 36, the charging station 36 switches to the second operating mode under control of the control unit 32. In the second operating mode, a charging current flowing through the charging cable 31 is limited to a small value, possibly to OA. At the same time, the locking element 11 of the connector 10 is set to a deactivated state via the control unit 32. In the example shown in FIGS. 4b, 5b, the locking means 16 on one side of the bridge 15 is released, which is symbolized by an open circle in FIG. 5b. In the deactivated state of the first locking element, the bridge 15 is mechanically connected to the housing 13 of the connector 10 at one end only. The connection is designed to be rotatable. In the event of a relative movement of the connector 10 and the mating connector 20, for example in response to an attempt to disconnect the connection, the bridge 15 flips outwards and releases the edge region 14 of the receiving opening 12 to one side, down to the opening distance d. The opening distance d is selected here to exceed a diameter of the pin 22. The second locking element 21 of the mating connector 20, which second locking element is designed as a pin 22, can thus be moved out of the receiving opening 12 of the connector 10 even when the second locking element 21 is in the activated state. The connection is unlocked and disconnection between the connection between connector 10 and the mating connector 20 is made possible, which is symbolized in FIG. 4b by an arrow on the connector 10 pointing away from the mating connector 20.

1. A method for locking a connection between a connector and a mating connector arranged on an electric vehicle, wherein the connector is arranged on a charging cable connected to a charging post of a charging station, wherein the charging cable is fixedly connected to the charging post of the charging station,
wherein the connector is associated with a first locking element, and the mating connector is associated with a second locking element, wherein the first locking element and the second locking element cooperate to lock the connection between the connector and the mating connector and each have an activated state and a deactivated state, comprising:
operating the first locking element associated with the connector in the activated state in a first operating mode of the charging station to lock the connection between the connector and the mating connector when the second locking element associated with the mating connector is activated; and
operating the first locking element associated with the connector in the deactivated state in a second operating mode of the charging station to unlock the connection between the connector and the mating connector when the second locking element associated with the mating connector is activated.

2. The method as claimed in claim 1, wherein the first locking element is activated and/or deactivated electromotively or electromagnetically.

3. The method as claimed in claim 1, wherein in the first operating mode of the charging station a charging process of the electric vehicle takes place, and wherein in the second operating mode of the charging station the charging process of the electric vehicle does not take place.

4. The method as claimed in claim 1, further comprising transitioning from the activated state of the first locking element to the deactivated state of the first locking element depending on a measurement of electrical variables in the connector and/or in the charging post of the charging station.

5. The method as claimed in claim 1, further comprising transitioning from the activated state of the first locking element to the deactivated state of the first locking element via an actuator driven by a magnetic field generated by a charging current.

6. The method as claimed in claim 1, further comprising transmitting a control signal for deactivating the first locking element associated with the connector from the charging post via a line configured for power transmission or a separate signal line of the charging cable.

7. The method as claimed in claim 1, wherein the first locking element associated with the connector comprises a receiving opening arranged in a housing of the connector, wherein the receiving opening comprises a closable edge region along its circumference, and wherein the second locking element associated with the mating connector has a displaceable pin which, in the activated state, engages the receiving opening of the first locking element.

8. The method as claimed in claim 7, wherein for unlocking the connector and the mating connector, the closable edge region of the receiving opening opens or is opened to an opening distance that exceeds a diameter of the displaceable pin so that the pin can be moved out of the receiving opening in the deactivated state of the first locking element.

9. The method as claimed in claim 7, wherein the closable edge region of the receiving opening is closed or narrowed via a lockable bridge, which is rotatably or displaceably mounted in the housing in the deactivated state of the first locking element.

10. A charging station for an electric vehicle with a charging post and a charging cable connected to the charging post, wherein the charging cable is fixedly connected to the charging post, and a connector arranged on the charging cable,
wherein the connector is configured to establish a locked connection to a mating connector of the electric vehicle, and for this purpose has a first activatable and deactivatable locking element configured to cooperate with a second activatable and deactivatable locking element of the mating connector for the purpose of the locking operation,
wherein the charging station is configured and set up in a first operating mode to operate the first activatable and deactivatable locking element associated with the connector in an activated state to lock the connection between the connector and mating connector when the second activatable and deactivatable locking element of the mating connector is activated, and wherein the charging station is configured and set up in a second operating mode to operate the first activatable and deactivatable locking element associated with the connector in a deactivated state to unlock the connection between the connector and the mating connector when the second activatable and deactivatable locking element of the mating connector is activated,
wherein the charging station comprises a control unit configured to actuate the connector, which control unit is configured to lock the connection between the connector and the mating connector by a method according to claim 1.

11. The charging station as claimed in claim 10, wherein the first activatable and deactivatable locking element associated with the connector comprises a receiving opening arranged in a housing of the connector and has a closable edge region along a periphery of the receiving opening, and in the first operating mode of the charging station is configured to at least partially enclose a second locking element configured as a pin, in its activated state in such a way that movement of the activated second activatable and deactivatable locking element out of the receiving opening is suppressed.

12. The charging station as claimed in claim 11, wherein the first activatable and deactivatable locking element in the deactivated state is configured and set up to open a previously closed edge region of the receiving opening or to increase an opening distance of a previously not completely closed edge region such that the opening distance exceeds a diameter of the second locking element designed as the pin.

13. The charging station as claimed in claim 12, wherein the first locking element comprises a bridge that is rotatably or slidably mounted in the housing in the deactivated state of the first activatable and deactivatable locking element.

14. The charging station as claimed in claim 10, wherein the first activatable and deactivatable locking element comprises an electromotive drive or an electromagnetic release device.

15. The charging station as claimed in claim 10, further comprising a measuring device connected to the control unit, the measuring device configured to detect electrical variables, wherein the control unit is configured and set up to operate the charging station in the first operating mode or in the second operating mode depending on the detected electrical variables.

16. The charging station as claimed in claim 10, further comprising a signaling device configured to indicate a currently present operating mode of the charging station.

17. The charging station as claimed in claim 10, further comprising a lockable emergency switch configured to set the charging station into the second operating mode to unlock a connection between the connector and mating connector when the second activatable and deactivatable locking element of the mating connector is activated.
